(19) United States
(12) Patent Application Publication
(10) Pub. No.: US 2007/0062730 A1
(43) Pub. Date: Mar. 22, 2007

(54) CONTROLLED DEPTH ETCHED VIAS

(75) Inventor: Thomas D. Murry, Springfield, MO (US)

Correspondence Address: MARSTELLER & ASSOCIATES, P.C., PO BOX 803302, DALLAS, TX, 75380-3302, US

(73) Assignee: LITTON SYSTEMS, INC., Los Angeles, CA (US)

(21) Appl. No.: 11/306,730

(22) Filed: Jan. 9, 2006

Related U.S. Application Data
(60) Provisional application No. 60/595,981, filed on Aug. 22, 2005.

(51) Int. Cl. H05K 1/11

(52) U.S. Cl. 174/266

(57) ABSTRACT

A printed circuit board (20) includes a sub-assembly having dielectric (22) and conductive layers (24). A hole (26) extends into the sub-assembly. Metal plating (32) is applied on a barrel (27) of the hole (26). A conductive layer (32) and an etch resist (34) are applied to a first photoresist (30) on the hole barrel (27). The first photoresist (30) is removed and a second photoresist (36) is applied leaving areas to be controlled depth etched exposed. The exposed areas (38) are chemically etched. The second layer of photoresist (36) is removed and a second chemical etch operation is performed to define previously plated features (40) on the sub-assembly (20). The etch resist (34) is then removed.

### CROSS REFERENCE TO RELATED APPLICATIONS

This application claims the benefit of U.S. Provisional Application Ser. No. 60/595,981, filed Aug. 22, 2005, entitled CONTROLLED DEPTH ETCHED VIAS.

### BACKGROUND OF THE INVENTION

1. Technical Field

The invention relates to the field of wiring boards for electronic devices, and more particularly to methods for electrical isolation of vias from either side of a printed circuit board.

2. Background Art

Electrical isolation of electronic components forming a part of printed circuit boards (PCBs) may be achieved using selected vias or conduits formed in the printed circuit board during the design and manufacture of the printed circuit board.

A prior method, which could be used to solve this problem, is known in the industry as sequential lamination and controlled depth drilling or milling. Sequential lamination is a process whereby a partial group of layers is processed through the normal multilayer lamination process, drilled and plated, and then combined with other parts in a subsequent lamination operation to yield the completed assembly. Controlled depth drilling or milling is used to tune the vias or create disconnects in selective locations for the purpose of increasing circuit density and/or lowering parasitic signal loss.

Sequential lamination adds significant cost to the end product through multiple repetitions of drilling, plating, imaging, and lamination processes. The repetitive processes in the prior method add significant cost to the manufacturing process. Controlled depth drilling is subject to a tolerance for the depth, the risk of drill breakage, and the system requires a flat surface prior to the start of the process. However, printed circuit boards are often not flat due to material variation, cloth style and weave used in the processing. Also, PCBs are often not flat at the necessary location where in the process sequence the depth drilling or milling is to be done.

While the above cited references introduce and disclose a number of noteworthy advances and technological improvements within the art, none completely fulfills the specific objectives achieved by this invention.

### DISCLOSURE OF INVENTION

In accordance with the present invention, a printed circuit board includes a sub-assembly having dielectric and conductive layers. A hole extends into the sub-assembly. Metal plating is applied on a barrel of the hole. A conductive layer and an etch resist are applied to a first photoresist on the hole barrel. The first photoresist is removed and a second photoresist is applied leaving areas to be controlled depth etched exposed. The exposed areas are chemically etched. The second layer of photoresist is removed and a second chemical etch operation is performed to define previously plated features on the sub-assembly. The etch resist is then removed.

The present invention is a printed circuit board processing technique that allows electrical isolation of select vias from either side of printed circuit board. The disclosed process is usable in buried, blind or finished vias. The present invention is realized through a sequence of controlling photo-tools and subsequent etching on feed-through vias. The present method keeps plating from the product surface on one side allowing for standard etching techniques to remove copper connecting via to surface. The present invention also allows tuning of vias through depth etching. Chemical etching is insensitive to printed circuit board thickness variations resulting in consistent depths of removed portion of via. This decreases parasitic signal loss due to material/design considerations.

Optimization of signal integrity requires tight control of the portion of the through via being removed. Using milling or controlled depth drilling the amount of via removed is dependent on z-axis variations in the printed circuit board. Additionally controlled depth drilling or mechanical milling is time consuming and expensive. Control depth etching allows for the creation of tuned vias from both sides of a panel at the same time. Depth control is achieved chemically. This process permits more complex product through the ability of disconnecting selectively from either side of the product.

The present invention minimizes repetition of process steps and allows for manufacturing of product using controllable processes. The present invention results in a product that is tuned to minimize parasitic signal loss without having to know material thickness variation.

These and other objects, advantages and preferred features of this invention will be apparent from the following description taken with reference to the accompanying drawings, wherein is shown the preferred embodiments of the invention.

### BRIEF DESCRIPTION OF DRAWINGS

A more particular description of the invention briefly summarized above is available from the exemplary embodiments illustrated in the drawing and discussed in further detail below. Through this reference, it can be seen how the above cited features, as well as others that will become apparent, are obtained and can be understood in detail. The drawings nevertheless illustrate only typical, preferred embodiments of the invention and are not to be considered limiting of its scope as the invention may admit to other equally effective embodiments.

FIG. 1 is a cross sectional view of a known laminated four layer printed circuit board before the process of the present invention is applied.

FIGS. 2 through 11 are a progression of cross sectional views of the printed circuit board of FIG. 1 after the various processing steps of the present invention have been applied.

### MODE(S) FOR CARRYING OUT THE INVENTION

So that the manner in which the above recited features, advantages and objects of the present invention are attained can be understood in detail, more particular description of the invention, briefly summarized above, may be had by reference to the embodiment thereof that is illustrated in the appended drawings. In all the drawings, identical numbers represent the same elements.

For illustrative purposes a simple four-layer printed circuit board (PCB) type product 20 will be described. The disclosed method can be used for multiple layers of PCB product 20. For example the four-layer product 20 may be a subset or sub-lamination of a thicker PCB.

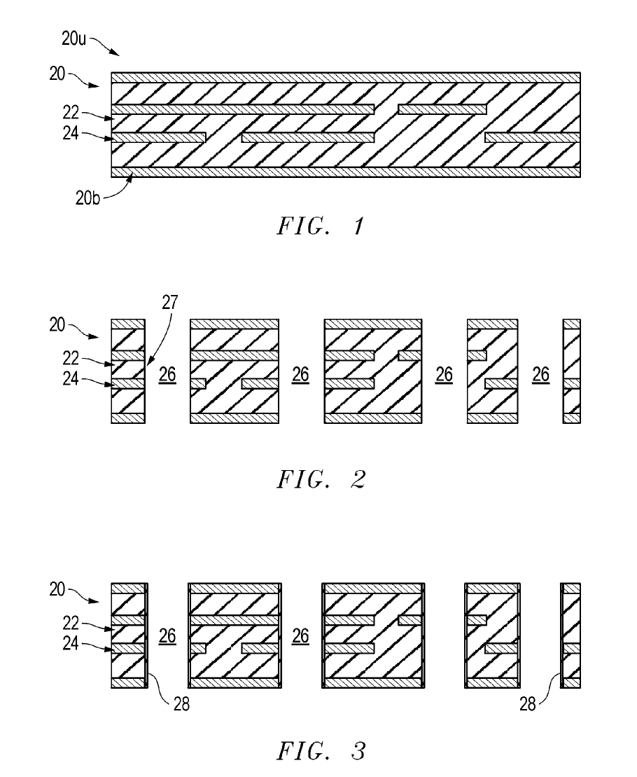

1. Generally, the desired layers of dielectric material 22, a conductive material 24, such as copper, or other desired component materials or layers are laminated together using a known technique to form the base for the product 20 having an upper surface 20u and a lower surface 20b. Note that this could be a sub-lamination for a thicker product. See FIG. 1.

2. With reference to FIG. 2, a known or standard drill or laser gouging operation is then performed through a portion of or completely through the sub-assembly 20 in accordance with the desired electrical circuit design to create holes. Holes or vias 26 are thereby created either partially or completely though the PCB 20 from the upper surface 20u to the lower surface 20b.

3. The surfaces of holes or conduits 26 are then conditioned by an application of a known conditioning material 28 to allow metal plating on dielectric. Any process that allows for metal to be plated onto a dielectric surface may be used in this step of the present method. Such suitable processes may include electroless copper, carbon, palladium, etc. This part of the present invention is a normal step for creating electrically conductive vias and is well known in the art. See FIG. 3.

4. A first photoresist 30 may be applied with specialized artwork (not shown) using a known technique. Artwork modification may be necessary to create the ability to control depth in the specific application of the present invention.

The photoresist 30 is a known material that is used to define where plating is to take place on the PCB 20. The artwork used in the application of the photoresist is modified to allow plating only on a surface of the hole or the hole barrel; and, there should be no plating on the surface, if appropriate for the specific PCB design. The photoresist 30 step is important to an understanding how the present invention works. With the plating only to the surface, the end of the hole barrel is exposed to the etch solution. This is critical to creating the depth etched feature. To etch down into the hole barrel without etching the whole barrel, the etch resist 34 must coat only the barrel 27 of the via 26 allowing the end of the barrel at the junction with either the upper surface 20u or lower surface 20b to be exposed. The artwork or photo-tool is modified to create a minimal pad on the surface 20u or 20b.

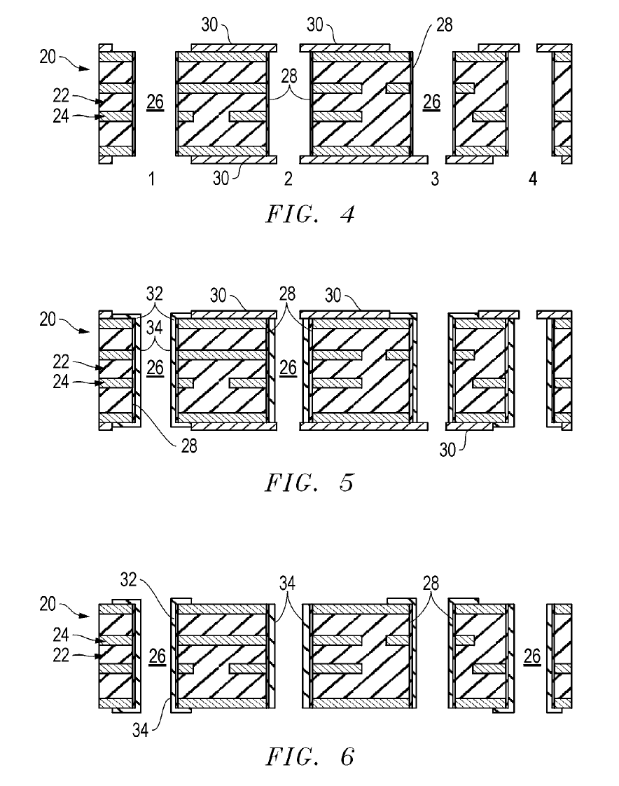

With reference to FIG. 4, a via or hole 26 is labeled 1 and is by way of example a standard plated through hole. The variation labeled as 1 is shown for comparison to three other variations labeled as variations 2 through 4 and shown in FIG. 4 and subsequent figures. Note that the shown variations of vias 26 are not all variations that may be possible. The four total variations shown are exemplary to demonstrate the potential types of vias suitable for the present invention.

5. FIG. 5 shows electroplated copper or other selected conductive material or layer 32 in or about the vias 26. An etch resist 34 may also be applied to the exposed surface of the applied copper material 32 or directly to the surface of or about the vias 26.

The etch resist 34 may be a tin/lead based etch resist as an example, but there are many suitable known types that may be appropriate for the specific application.

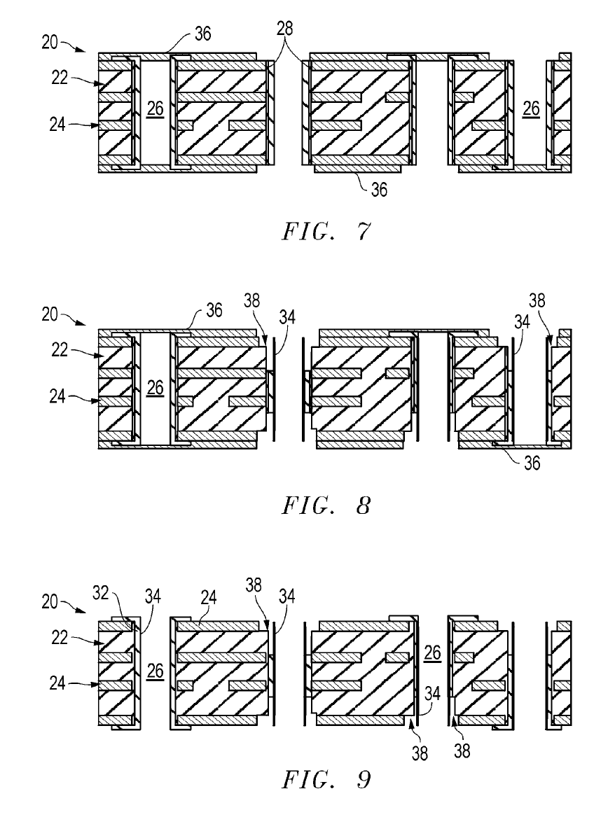

6. FIG. 6 shows that the photoresist 30 as having been subsequently removed in a succeeding process step after the application of the conductive material 32 or etch resist 34.

7. A second photoresist layer 36 is then applied for the desired application. This second photoresist layer 36 is applied to expose the areas to be controlled depth etched and to prevent etching of copper 32 in areas that may need additional processing. See FIG. 7.

8. Next, a known chemical etching method suitable for the materials is used to expose controlled areas resulting from the previous operation. See FIG. 8.

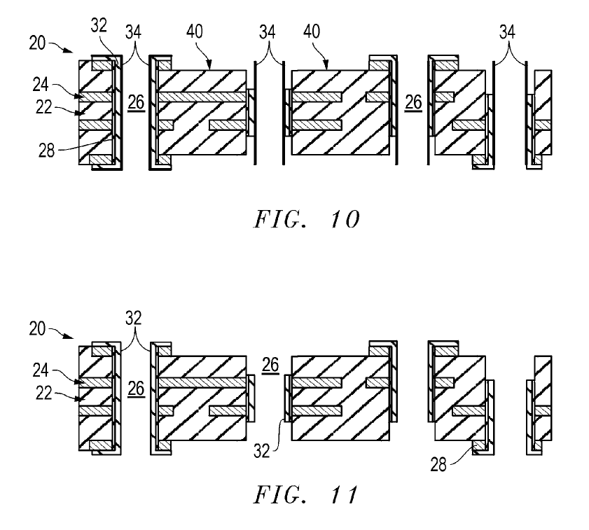

9. The second layer of photoresist 36 is then removed. See FIG. 9.

10. A second chemical etch operation is then performed. The present operation defines previously plated features on the PCB 20. Alternate processes may be used to define the resulting surface features such as print and etch. The features shown in the accompanying figures may be defined through pattern plating sequences. No surface circuitry is shown in the accompanying figures, although surface circuitry can be included as a surface feature. See FIG. 10.

11. Removal of etch resist 34 is then achieved through an appropriate and known method appropriate for the materials used. FIG. 11.

12. At this stage in the series of steps, the process is substantially complete.

Further processing steps may include embedding the product 20 into another PCB as a sub-lamination or the product 20 may be the final product that needs additional known processing steps as desired to the specific purpose.

The known or “normal” via formation in a PCB is to plate the hole and not remove any of the hole plating chemically. There are known operations categorized generally as “controlled depth drilling/milling” that removes part of the hole plating for “tuning,” but the hole plating removal is not done chemically.

Such known “controlled depth drilling/milling” technique would typically start with FIG. 4 and follow only hole 1 (left hand side of the cross sectional view). The prior process would move to the step shown in FIG. 5 next. This step is standard “through hole plating.” To finish the standard hole without creating control depth etching one would go to FIG. 9.

The description of the present method shows the removal of the etch resist and now copper is exposed everywhere for the FIG. 1 0 copper etching step of the present invention. Although it may seem that the steps shown in FIGS. 6 through 8 are not necessary, they do form an integral part of the present invention. Etching is an isotropic method, meaning that the copper etches equally fast in both the vertical and horizontal directions. The presently disclosed steps are necessary to prevent etching of features (printed circuits) away while etching the depth vertically wanted. For example, if one were to etch 0.005-inches deep into the hole barrel, that etching would undercut the circuitry by 0.010-inches (circuit is open from both sides). Since the circuitry is typically 0.004-inches and less below the surface, there would be no circuitry left on the surface.

The foregoing disclosure and description of the invention are illustrative and explanatory thereof, and various changes in the size, shape and materials, as well as in the details of the illustrated construction may be made without departing from the spirit of the invention.

What is claimed is:

1. A wiring board comprising:
a sub-assembly prepared by laminating a sequence of dielectric and conductive layers together;
a hole extending from at least one surface of the sub-assembly and through at least a part of the sub-assembly;
metal plating applied on a barrel of the hole;
a first photoresist being applied;
a conductive layer applied to the first photoresist in the barrel of the hole and selected other parts of the sub-assembly as desired; and, an etch resist layer applied to the conductive layer previously applied to the first photoresist in the barrel of the hole;
the first photoresist being removed before a second photoresist layer is applied in a manner to leave areas to be controlled depth etched exposed and to prevent etching of copper in other selected areas;
the exposed areas being chemically etched;
the second layer of photoresist being removed;
previously plated features on the sub-assembly being defined by a second chemical etch operation; and
the etch resist being removed.

2. The invention of claim 1 wherein the barrel of the hole is conditioned prior to the hole being metal plated.

3. The invention of claim 1 wherein the hole extending from at least one surface of the sub-assembly is formed by a laser gouging operation.

4. The invention of claim 1 wherein the hole extending from at least one surface of the sub-assembly is formed by a drilling operation.

5. The invention of claim 1 wherein a surface of the hole extending from at least one surface of the sub-assembly is conditioned with an application of a conditioning material for facilitating plating of metal onto a dielectric surface.

6. The invention of claim 5 wherein the conditioning material for facilitating the plating of metal includes electroless copper.

7. The invention of claim 1 wherein the etch resist is tin based.

8. The invention of claim 1 wherein the etch resist is lead based.

9. A method for forming at least a portion of a wiring board comprising the steps of:
preparing a sub-assembly by laminating a sequence of dielectric and conductive layers together;
creating a hole extending from at least one surface of the sub-assembly and through at least a part of the sub-assembly;
applying metal plating on a barrel of the hole;
applying a first photoresist;
applying a conductive layer to the first photoresist in the barrel of the hole and selected other parts of the sub-assembly as desired; and, applying an etch resist layer to the conductive layer previously applied to the first photoresist in the barrel of the hole;
removing the first photoresist;
applying a second photoresist layer in a manner to leave areas to be controlled depth etched exposed and to prevent etching of copper in other selected areas;
chemical etching of exposed areas;
removing the second layer of photoresist;
performing a second chemical etch operation to define previously plated features on the sub-assembly; and
removing the etch resist.

10. The method of claim 9 further including the step of conditioning the barrel of the hole prior to the hole being metal plated.

11. The method of claim 9 wherein the hole extending from at least one surface of the sub-assembly is created by a laser gouging operation.

12. The method of claim 9 wherein the hole extending from at least one surface of the sub-assembly is formed by a drilling operation.

13. The method of claim 9 further including the step of applying a conditioning material for facilitating plating of metal onto a dielectric surface to a surface of the hole extending from at least one surface of the sub-assembly.

14. The method of claim 13 wherein the conditioning material for facilitating the plating of metal includes electroless copper.

15. The method of claim 9 wherein the etch resist is tin based.

16. The method of claim 9 wherein the etch resist is lead based.
